(19) United States
(12) Patent Application Publication
(10) Pub. No.: US 2005/0247339 A1
(43) Pub. Date: Nov. 10, 2005

(54) Method of operating a solar cell

(75) Inventors: Keith William John Barnham, London (GB); Massimo Mazzer, Vittorio Veneto (IT); James Patrick Connolly, London (GB)

Correspondence Address: NIXON & VANDERHYE, PC, 901 NORTH GLEBE ROAD, 11TH FLOOR, ARLINGTON, VA, 22203, US

(73) Assignee: Imperial College Innovations Limited, London (GB)

(21) Appl. No.: 10/841,843

(22) Filed: May 10, 2004

(51) Int. Cl. H01L 31/00

(52) U.S. Cl. 136/262; 136/261; 136/252

(57) ABSTRACT

A method of operating a solar cell is provided in which strain balanced multiple quantum well stacks containing greater than 30 quantum wells disposed between bulk semi-conductor regions having a band gap differences between the deepest well of the stack and the bulk semi-conducting region of greater than 60 mev is irradiated with radiation having an intensity of greater than 100 suns. Photons are absorbed with and outside of the quantum well stack to generate electron hole pairs recombination of electrons and holes is substantially only via a radiative recombination mechanism.

### BACKGROUND OF THE INVENTION

1. Field of the Invention

This invention relates to the field of solar cells for generating electrical energy. More particularly, this invention relates to a method of operating a solar cell containing a strain balanced multiple quantum well stack.

Description of the Prior Art

It is known that the optimum band-gap for a single-junction solar cell in typical terrestrial illumination at light concentrations between 30 and 1000× is equivalent to an absorption edge of around 1.1 μm as is shown in FIG. 1 of the accompanying drawings [1]. In order to achieve improved efficiencies within solar cells, which are significantly higher than the current record for a single junction cell of 27.6% at 255× GaAs cell [2], requires that the absorption edge should be moved close to 1.1 μm together with a reduction in recombination losses.

There are no binary or ternary III-V compounds that can reach the band-gap required for such an absorption edge of 1.1 μm while remaining lattice matched to any substrate currently available. The absorption edge condition can be achieved by growing the ternary compounds with the appropriate band-gap on virtual substrates whose equilibrium lattice parameter is adjusted through the controlled plastic relaxation of a buffer layer grown on a GaAs or Ge substrate. However, unavoidable misfit and threading dislocations from the virtual substrate ensure non-desired recombination mechanism are still present. Quaternary III-V compounds could fulfil the absorption edge condition while remaining lattice matched to GaAs, but the material is of such poor quality that achieving low recombination loses is at present unlikely. Strained GaAs/InGaAs quantum wells can achieve band-gaps that approach the desired band-gap, but the strain limits the number of quantum wells that can be incorporated without introducing dislocations and, below or above that limit, the current gain compared to a GaAs cell is insufficient to overcome the voltage loss. Efficiencies higher than GaAs cells cannot currently be achieved with strained GaAs/InGaAs multiple quantum wells [3].

The highest efficiency single junction cell, which is made of GaAs, has an efficiency of 27.6% at 225×. This record was established in 1991 and has not been superseded by a single-band gap cell [2]. This record efficiency is significantly below the maximum efficiency of around 30% expected from FIG. 1, and considerably below the 35.2% efficiency at 225× expected at the thermodynamic limit according to the approach of Henry [4]. Therefore the main progress in raising the limit in PV cells for the past decade has been in developing tandem and other multi-junction cells. In these devices, it is generally accepted that the next major efficiency improvement will come by adding a fourth cell with band-gap around 1.24 μm to the high efficiency GaInP/GaAs/Ge three-junction cell [5].

The series current constraint in a monolithic multi-junction cell means that a cell optimised for specific spectral conditions will lose efficiency under the variable spectral conditions found in many terrestrial concentrator applications. At the same optimal efficiency, a single-junction cell is therefore preferable to a tandem cell in a terrestrial concentrator.

### SUMMARY OF THE INVENTION

Viewed from one aspect the present invention provides a method of operating a solar cell having a strain balanced multiple quantum well stack containing greater than thirty quantum wells and disposed between bulk semiconductor regions, a band-gap difference between a band-gap of a deepest well within said strain balanced multiple quantum well stack and a band-gap of said bulk semiconductor regions of the cell outside the multiple quantum well region being greater than 60 meV, said method comprises the steps of:

receiving incident radiation having an intensity of greater than one hundred suns concentration;

absorbing photons from said incident radiation both within and outside said quantum well stack to generate electron hole pairs;

recombining electrons and holes with a radiative recombination mechanism to form re-radiated photons that are re-absorbable within said solar cell to generate electrical energy; wherein

electrons and holes within said quantum well stack substantially only recombine via said radiative recombination mechanism.

The present technique recognises that using a strain balanced multiple well quantum stack with greater than 30 quantum wells, which may be achieved without dislocations using strain balancing techniques, coupled with an appropriately matched bulk semi-conductor region bounding the quantum well stack enables high efficiency to be achieved and radiative recombination to dominate in a manner that the photons generated by such radiative recombination can be re-used. Whilst as previously discussed the absorption edge should be close to 1.1 μm, significant in advantages result in embodiments in which the absorption edge is above 0.9 μm.

So that radiative recombination will dominate in an advantageous manner, preferred embodiments of the invention are such that a p region and an n region within the solar cell are provided having a band gap greater than a photon energy corresponding to an absorption edge of the solar cell so as to suppress Shockley recombination of electrons and holes.

The efficiency of the solar cell may be further enhanced by the use of a Bragg stack or multiple-layer reflector beneath the solar cell to reflect radiation with an energy between an absorption edge of the quantum well stack and an absorption edge of the bulk semi-conductor region back into the quantum well stack.

Whilst the above techniques may be advantageously used within a single junction cell, they may be particularly advantageously employed within a solar cell which is a tandem solar cell having a further absorption region beneath the quantum well stack with a band gap matched the re-radiated photons to absorb these with a high probability.

The further absorption region could take a variety of forms, such as a simple bulk semi-conductor junction. However, in preferred embodiments, the further absorption region is a further strain balanced multiple quantum well stack having greater than 30 quantum wells.

An alternative further absorption region which is preferred in other circumstances is an active Germanium substrate.

Whilst it will be appreciated that the quantum well stacks may be formed in a variety of different ways in preferred embodiments the quantum well stack is are formed as one of:
GaAs₁₋ₓPₓ/In_{y}Ga_{1-y}As layers, where x and y are chosen so that an equilibrium lattice parameter of said quantum well stack as a free standing structure is equal to a lattice parameter of a substrate of said solar cell for a given absorption edge and produce strain-balanced quantum well layers and quantum well barriers.
GaₓIn₁₋ₓP/In_{y}Ga_{1-y}As layers, where x and y are chosen so that an equilibrium lattice parameter of said quantum well stack as a free standing structure is equal to a lattice parameter of a substrate of said solar cell for a given absorption edge and produce strain-balanced quantum well layers and quantum well barriers.
GaAs₁₋ₓPₓ/In_{y}Ga_{1-y}AsN_{z} layers, where x, y and z are chosen so that an equilibrium lattice parameter of said quantum well stack as a free standing structure is equal to a lattice parameter of a substrate of said solar cell for a given absorption edge and produce strain-balanced quantum well layers and quantum well barriers and z represents the addition of a small proportion of Nitrogen atoms
   In the case of a tandem solar cell a further absorption layer may advantageously be formed as one of:
a quantum well stack comprising GaₓIn₁₋ₓP/Ga_{y}In_{1-y}P layers, where x and y are chosen to substantially minimise stress and said further strain balanced multiple quantum well stack comprises GaAs₁₋ₓPₓ/In_{y}Ga_{1-y}As layers where x and y are chosen so that a equilibrium lattice parameter of said further stack as a free standing structure is equal to a lattice parameter of a substrate of said tandem solar cell for a given absorption edge.
a quantum well stack comprising GaₓIn₁₋ₓP/Ga_{y}In_{1-y}P layers, where x and y are chosen so that an equilibrium lattice parameter of said quantum well stack as a free standing structure is equal to the lattice parameter of a substrate of said tandem solar cell for a given absorption edge and said further strain balanced multiple quantum well stack comprises GaAs₁₋ₓPₓ/In_{y}Ga_{1-y}AsN_{z} where x, y and z are chosen to substantially minimise stress.

The above, and other objects, features and advantages of this invention will be apparent from the following detailed description of illustrative embodiments which is to be read in connection with the accompanying drawings.

### BRIEF DESCRIPTION OF THE DRAWINGS

FIG. 1 schematically illustrates efficiency against band-gap wavelength at 30 and 1000 suns intensity with an AM 1.5 d spectrum taken from Ref. 1.

FIG. 2 shows tables quantifying dark-current levels;

FIG. 3 is a contour plot showing efficiency of a tandem cell;

FIG. 4 is a plot showing measured and fitted dark-current of a strain balanced quantum well solar cell;

FIG. 5 is a plot showing mean measurements of the zero voltage intercept of the n=1 dark-current of various devices;

FIG. 6 is a plot showing the relative fraction of the radiatively limited current as a function of cell band-edge;

FIG. 7 is a schematic illustration of one possible example embodiment of a tandem solar cell arrangement including double strain balanced quantum well active regions;

FIG. 8 schematically illustrates the band-gap structure of a double strain balanced multiple quantum well solar cell tandem arrangement; and

FIG. 9 schematically illustrated a predicted spectral response of the tandem solar cell of FIGS. 7 and 8.

### DESCRIPTION OF THE PREFERRED EMBODIMENTS

Here we describe a photovoltaic cell, strain-balanced quantum well solar cell (SB-QWSC) that can substantially simultaneously fulfil the absorption edge and recombination conditions previously discussed. This cell can achieve both conditions with current III-V or II-VI materials. One embodiment of the SB-QWSC is that it has a p and n doped region formed from GaAs and an undoped i-region formed from a GaAs₁₋ₓPₓ/In_{y}Ga_{1-y}As strain-balanced quantum well system where the P composition (x) and the In composition (y) are chosen to ensure that the GaAsP barrier has higher band-gap than the bulk region of the cell and that there is minimum shear force between adjacent layers [6]. The difference in the band gap of the deepest well in the quantum well structure and the band gap of the surrounding bulk semiconductor regions is greater than 60 meV, the bandgap of the bulk semiconductor being greater. The typical number of wells in such a system is around 50. As a result of strain-balancing with the recipe (methodology) taught in Ref. 6 (the disclosure of which is incorporated herein by reference) such systems have substantially no dislocations [3, 7]. This is in contrast to bulk InGaAs of similar band-edge grown on relaxed substrates or strained GaAs/InGaAs MQW systems as proposed in Ref. 8. In the latter case 25 wells will produce relaxation and a catastrophic rise in dark-current. [3].

An absorption edge of substantially 1.1 μm can be fufilled by quantum well cells that are strain-balanced according to the teaching of Ref. 6 with around 50 wells and without the introduction of dislocations. The addition of a small amount of Nitrogen in the InGaAs well can help to ensure the optimum absorption threshold can be achieved in the presence of no plastic relaxation in the whole structure of the cell

An unexpected advantage of the SB-QWSC is that, as will be discussed below, for the deep quantum wells appropriate to the absorption edge of 1.1 μm, the cells are radiative recombination dominated. It has recently been demonstrated that at current levels corresponding to 200× concentration and above the diode dark current of SB-QWSCs show ideal behaviour with ideality factor n=1 [10]. Ideality n=1 behaviour, though necessary for radiative recombination, is not a sufficient condition. Ideal Shockley behaviour with non-radiative recombination in the p and n regions also gives n=1 [11].

Analysis of the present cells suggests that the radiative recombination is a result of a number of features of the SB-QWSC:
1) Crystal structure at least as good as GaAs if the stress-balance condition of Ref. 6 holds.
2) The absence of any plastic relaxation if the stress-balance condition of Ref. 6 holds.
3) A high proportion of the i-region consists of high band-gap barriers, which are higher than in the p or n regions. Recombination via both ideality n=1 and ideality n=2 mechanisms is reduced exponentially with the band-gap energy [11] and so recombination in the wells dominates over recombination from the barrier region.
4) The p and n regions of the cell where the ideal Shockley recombination occurs has a significantly higher band-gap than the absorption edge of the cell and hence this results in a negligible contribution to the n=1 current for wells deeper than the bulk region bandgap by more than 60ₘₑV.
5) Recombination is dominated by the quantum well contribution (although we have experimental evidence that this contribution is lower than expected as in Ref. 14 discussed below) which occurs in the i-region where the doping is minimal and the material quality optimal for band to band recombination. By contrast in a p-n bulk GaAs cell the recombination occurs in doped p or n regions. In the case of the emitter, the doping is generally high, the emitter relatively thin, and surface recombination cannot be neglected.

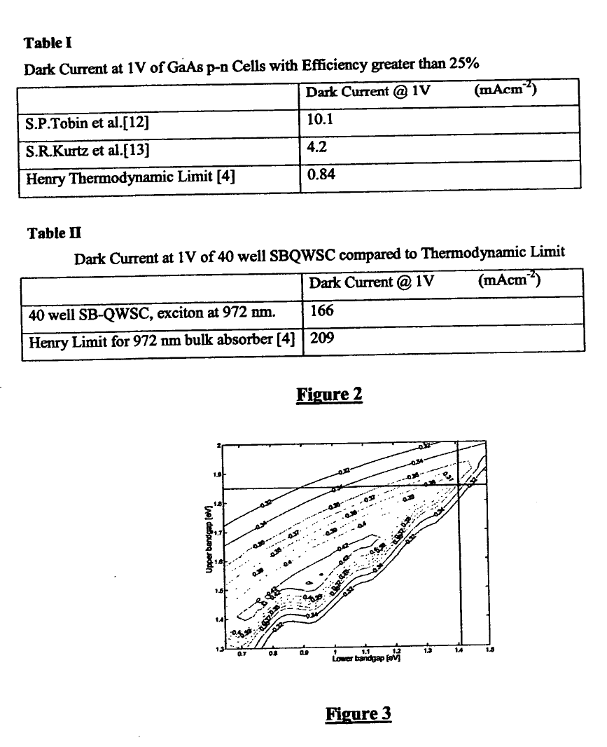

As examples we show in Table I of FIG. 2 the published dark-current at 1 V from two high efficiency (above 25% terrestrial efficiency) cells compared with the prediction of a radiative recombination model, namely the Thermodynamic Model of Ref. 4. It should be noted that both the high efficiency cells have significantly higher (i.e. worse) dark current than the radiative model. By contrast in Table II of FIG. 2 a 40 well SB-QWSC with exciton position corresponding to an absorption edge of 972 nm has a lower (i.e. better) dark current than the radiative model of Ref. 4 would predict for an ideal absorber at absorption edge of 972 nm. That the thermodynamic prediction is above the experiment probably reflects the fact that the SB-QWSC is not a perfect absorber at the band-edge. However, there is a possibility that the reduction in radiative recombination is a further example of the suppression of radiative recombination in quantum well solar cells [14].

Viewing the present techniques in another way, they may also be considered as follows.

Monolithic tandem and triple junction GaInP/GaAs cells on active or passive Ge substrates achieve the highest currently known photovoltaic efficiencies and are employed to power satellites in space. Their use in terrestrial applications is limited by their cost, which can be reduced by using light-concentrating systems, and the need to reduce the upper and lower band-gaps to achieve the highest terrestrial efficiencies.

It is established that the efficiency of GaInP/GaAs based multi-junction cells is limited by the current produced by the GaAs cell. It has been shown that replacing the lower GaAs bulk cell in a GaInP/GaAs tandem by a GaAsP/InGaAs SB-QWSC will enable higher efficiencies to be achieved [15]. FIG. 3 (Contour plot showing efficiently of GaInP/SB-QWSC tandem efficiency when operating at 300 suns concentration in AM1.5D spectrum as a function of upper-cell and lower cell absorption band-edge. Where the black lines intersect indicates the efficiency of a GaInP/GaAs tandem) gives a calculated contour plot showing the efficiency of a GaInP/SB-QWSC combination as a function of upper and lower cell band-gap in typical terrestrial conditions (AM1.5D) at 300× concentration. The strong correlation of the contours with the two band-gaps results from the requirement that the series current be the same in the monolithic, two-terminal device. FIG. 3 shows that for terrestrial concentrator applications it is clearly advantageous to lower the band-gap of both upper and lower cells. The way this is currently being done for conventional cells is to grow a GaInP/InGaAs tandem on a relaxed or virtual substrate [16,17]. This introduces unavoidable, deleterious dislocations. Unlike the tandem cells grown on virtual substrates, the SB-QWSC exhibits a complete absence of dislocations [7]. Furthermore the upper cell band-gap in a tandem cell grown on a virtual substrate is constrained to a particular value by the relaxed lattice constant, which fixes the values of the upper and lower cell band-gaps.

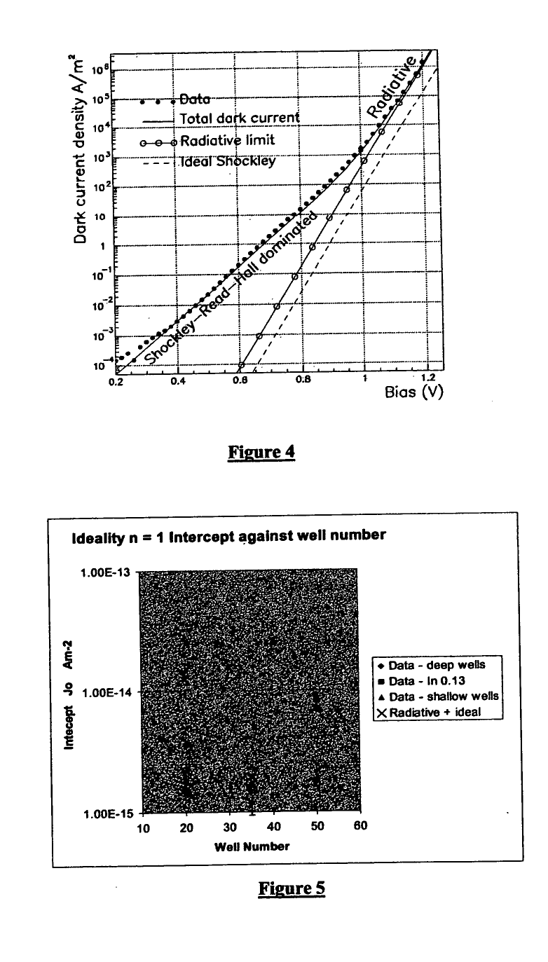

The advantages of a GaInP/SB-QWSC tandem over the GaInP/InGaAs tandem on a virtual substrate are:
1) The band-gap of the lower SB-QWSC cell can be adjusted independently of the band-gap of the upper cell by altering the composition of the wells and barriers and the well width
2) The band-gap can be adjusted without introducing dislocations.
3) A third advantage of the SB-QWSC for concentrator applications is that it has recently been demonstrated that at current levels corresponding to 200× concentration and above the diode dark current shows ideal behaviour with ideality factor n=1. A typical example is given in FIG. 4 (Measured and fitted dark-current of a typical 50 well SB-QWSC showing that at high current levels the diode current is dominated by ideal behaviour. A concentration of 200× corresponds to a current of approximately 5.10⁴ Am⁻² The curve marked “radiative limit” is a detailed balance calculation of the radiative recombination in the quantum wells. The curve marked “ideal Shockley” is a calculation of the n=1 contribution in the neutral, bulk regions of the cell according to Shockley's prescription allowing for surface recombination.) Ideal behaviour corresponds to low recombination and hence high efficiency [15].
4) A further advantage of the SB-QSCS [18] is that the n=1 dark current becomes increasingly radiatively dominated as the wells get deeper. This ideal behaviour is as a result of the absence of dislocations due to the strain-balance condition and the presence of extensive high band-gap barriers which minimises recombination within the i-region.

There are two distinct contributions to the n=1 current. Firstly the standard, ideal Shockley diode current, which assumes no recombination in the depletion region. This contribution depends in a standard way on the minority carrier diffusion lengths, doping levels and the surface recombination in the neutral regions. We can estimate this current since the parameters concerned are important in the fits we make to the quantum efficiency (QE) at zero bias i.e. the spectral response (SR) of the cells. The second contribution to the n=1 current results from the recombination of carriers injected into the QWs. The non-radiative recombination can be described by a model [19] which explains the n˜2 behaviour at low current levels in FIG. 4, and which predicts that this term can be ignored at high currents. The radiative contribution to the QW recombination can be estimated by a detailed balance argument [20]. This relates the photons absorbed to the photons radiated, and depends on the quasi-Fermi level separation ΔE_{F} and the absorption coefficient α(E,F) as a function of energy and field. For this study we assume that ΔE_{F}=eV where V is the diode bias. There is evidence from strained single QW samples that ΔE_{F}<eV [21]. Such an effect would enhance the performance of the SB-QWSC but is not necessary for the efficient functioning of the novel device described here.

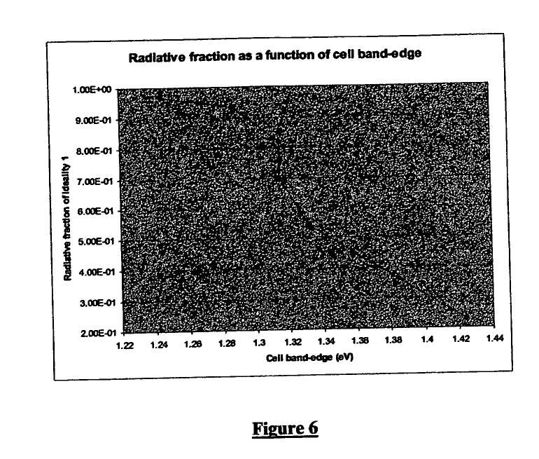

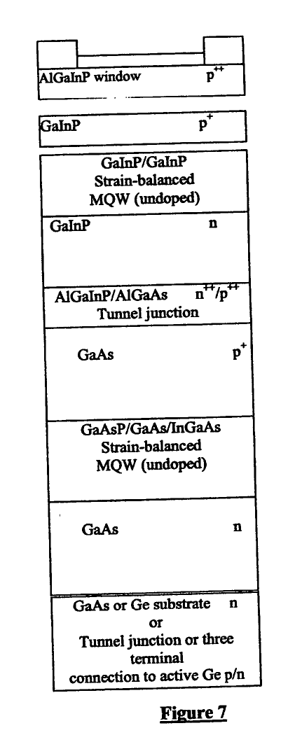

The important parameters for both the ideal Shockley (minority carrier diffusion lengths) and the QW radiative current levels (absorption coefficient α(E,F)) are therefore determined by the SR fits in the bulk and QW regions respectively. It can be seen from FIG. 5, (Mean of measurements of the intercept of the n=1 dark-current from fits to 8-18 devices with n˜2 and n=1 exponential terms. Data are plotted against number of wells and compared with the sum of QW “radiative limit” current plus “Ideal Shockley” current models) where the mean intercept from the experimental double-exponential fits is compared with the sum of the Ideal Shockley and QW radiative terms that good agreement is observed even though there are essentially no free parameters for the model. FIG. 6 (Ratio of QW “radiative limit” current to sum of “radiative limit” current plus “Ideal Shockley” current against QW absorption edge given by position of the first exciton in the quantum well) shows the absorption threshold energy dependence of the ratio of the QW radiative current intercept to the intercept of the total Ideal Shockley plus QW radiative currents. It can be clearly seen that the dark-current is becoming increasingly radiative dominated as the wells get deeper. The calculations show that the contribution to the recombination from the high-band-gap MQW barrier regions is negligible. This confirms that the wide, high-band-gap barriers that are a necessary for the strain-balance condition are important for the successful operation of this technique.

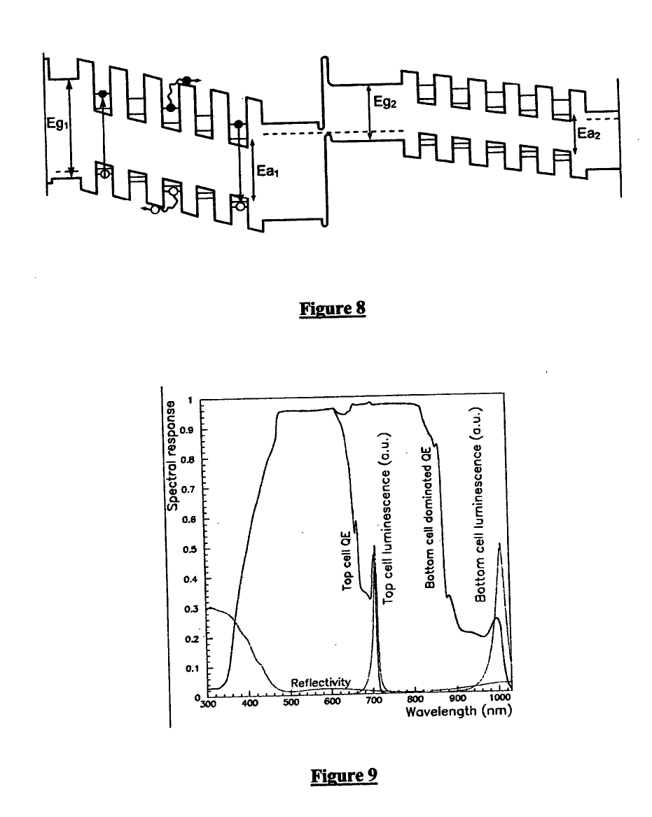

A typical structure for the novel cell in a monolithic GaInP/GaAs tandem system on a GaAs or Ge substrate or a GaInP/GaAs/Ge triple junction system on an active Ge substrate is shown in FIG. 7 (Schematic of one possible double SB-QWSC p- on n- arrangement with strain-balanced MQW cells as both upper and lower band gap cells. All doping types would be reversed in an n- on p- arrangement). The energy band-structure of the proposed arrangement is shown in FIG. 8 (Schematic of the band-edge structure of a double SB-QWSC p-on n- tandem arrangement. The device may be grown on a Distributed Bragg Reflector or other multiple layer reflector. This may be grown on a GaAs or Ge substrate. Alternatively a tunnel junction or three terminal connection can be made to an active Ge substrate). Other materials for top and bottom cell and other doping configurations are possible, in particular in a n-i-p configuration rather than the p-i-n configuration shown here.

The top QW stack may be formed of one of:
GaAs₁₋ₓPₓ/In_{y}Ga_{1-y}As layers, where x and y are chosen so that an equilibrium lattice parameter of said quantum well stack as a free standing structure is substantially equal to a lattice parameter of a substrate of said solar cell for a given absorption edge and produce strain-balanced quantum well layers and quantum well barriers.
GaₓIn₁₋ₓP/In_{y}Ga_{1-y}As layers, where x and y are chosen so that an equilibrium lattice parameter of said quantum well stack as a free standing structure is substantially equal to a lattice parameter of a substrate of said solar cell for a given absorption edge and produce strain-balanced quantum well layers and quantum well barriers.
GaAsₓP₁₋ₓ/In_{y}Ga_{1-y}AsN_{z} layers, where x, y and z are chosen so that an equilibrium lattice parameter of said quantum well stack as a free standing structure is substantially equal to a lattice parameter of a substrate of said solar cell for a given absorption edge and produce strain-balanced quantum well layers and quantum well barriers and z represents the addition of a small proportion of Nitrogen atoms.

The bottom tandem cell in the above three cases is an active Ge substrate connected by a tunnel junction or three terminal connection. A double quantum well stack as in FIG. 7 and FIG. 8 can be formed of one of:
a quantum well stack comprising GaₓIn₁₋ₓP/Ga_{y}In_{1-y}P layers, where x and y are chosen to substantially minimise stress and said further strain balanced multiple quantum well stack comprises GaAs₁₋ₓPₓ/In_{y}Ga_{1-y}As layers where x and y are chosen so that a equilibrium lattice parameter of said further stack as a free standing structure is substantially equal to a lattice parameter of a substrate of said tandem solar cell for a given absorption edge.
a quantum well stack comprising GaₓIn₁₋ₓP/Ga_{y}In_{1-y}P layers, where x and y are chosen so that an equilibrium lattice parameter of said quantum well stack as a free standing structure is substantially equal to the lattice parameter of a substrate of said tandem solar cell for a given absorption edge and said further strain balanced multiple quantum well stack comprises GaAs₁₋ₓPₓ/In_{y}Ga_{1-y}AsN_{z} where x, y and z are chosen to substantially minimise stress.

Both the above tandem cells can be grown on an active Ge substrate connected by a tunnel junction or three terminal connection.

A top cell with wide band-gap E_{g1} absorbs high energy photons and is connected by a tunnel junction or a three terminal connection to a lower cell with narrow band-gap of E_{g2}. A first feature of this cell is that the top cell is formed from a Ga₁₋ₓInₓP/Ga_{1-y}In_{y}P a strain-balanced quantum well solar cell where the In compositions x and y of the barrier and wells respectively are chosen to ensure that the barrier has higher band-gap than the bulk region of the cell and there is substantially minimum shear force between adjacent layers [6].

The lower cell of the proposed arrangement is formed from a GaAs₁₋ₓPₓ/In_{y}Ga_{1-y}As SB-QWSC where the P composition (x) and the In composition (y) are chosen to ensure that the GaAsP barrier has higher band-gap than the bulk region of the cell and that there is substantially minimum shear force between adjacent layers [6].

The first advantage of the double SB-QWSC tandem is that it will be possible to separately optimise the absorption band-edge of both the top and the bottom cell in a monolithic tandem so as to achieve optimal performance for given spectral conditions and temperature of operation, without introduction of dislocations. The absorption band-gaps of the top and bottom cell are given by Eₐ₁ and Eₐ₂ respectively in FIG. 8. They are determined by the energy difference between the confined levels in the QWs. These can be optimised by changing the well composition, well width and barrier composition separately in both the top and bottom cell while the maintaining the constraint that there is substantially minimum shear force between adjacent layers [6].

The double SB-QWSC tandem and the GaInP/SB-QWSC tandem are significantly different from the GaInP/Strained InGaAs tandem of Ref. 21 and have advantages over it as follows:
1) The GaInP/Strained InGaAs tandem of Ref. 21 does not have a MQW in the top cell of the tandem and hence the two band-gaps cannot be separately optimised for the highest efficiency. Furthermore the tandem cell cannot take advantage of photonic coupling in the way to be described below.
2) The wide, high band-gap barriers of the SB-QWSC, which are not present in the design of Ref. 21 are crucial in ensuring the strain-balance condition of Ref. 6 and in ensuring that the recombination is radiatively dominated.
3) There are no dislocations in the SB-QWSC structure if the condition of Ref. 6 holds. Hence considerably more wells can be incorporated than are possible in the case of strained InGaAs wells where catastrophic relaxation has been observed in practice [22, 23] for quantum well numbers lower than the 30 upper limit claimed in Ref. 21. In FIG. 4 of Ref. 23 there is a two-order of magnitude increase in dark-current on going from 10 to 23 wells. On the other hand, excellent material quality has been observed in the 50 well SB-QWSC whose dark-current is shown in FIG. 4.
4) In Ref. 23 we demonstrate that strained InGaAs quantum wells cannot enhance GaAs solar cell efficiency because insufficient wells can be grown to give sufficient current enhancement without relaxation occurring. Relaxation dramatically increases the dark-current and hence the voltage loss is greater than the current gain. Even if no relaxation occurs the dark-current in a stained InGaAs MQW is much higher than in a SB-QWSC of comparable band-gap and the voltage loss with strained InGaAs quantum wells is greater than the current gain. “It must be concluded that the dark-IV degradation suffered by strained GaAs/InGaAs cells is too great to surpass a good GaAs control in terms of AM0 conversion efficiency” [23].

A second feature of the double SB-QWSC arrangement is made practicable by the recent observation that as a result of the absence of dislocations and the higher band-gap barrier regions at concentrator current levels, radiative recombination dominates in SB-QWSCs [18]. The specific advantage of this for the double SB-QWSC can be appreciated with reference to the predicted spectral response for the device in FIG. 9 (Predicted spectral response for the novel tandem solar cell with top cell formed from a Ga₁₋ₓInₓP/Ga_{1-y}In_{y}P strain-balanced quantum well solar cell as top cell, and the lower cell of the invention is formed from a GaAs₁₋ₓPₓ/In_{y}Ga_{1-y}As SB-QWSC. The radiative recombination spectra calculated by detailed balance are also presented in arbitrary units). The radiative recombination from the top cell will be primarily at energies towards the bottom of the QW. It can be seen that the photons from the unavoidable radiative recombination in the top cell which is directed towards the substrate will be absorbed by the lower cell at an energy where the quantum efficiency of the bottom cell is very high and will contribute to the cell current. A fraction of the photons emitted away from the substrate will exit the device through the escape cone, which is small for these high refractive index (˜3.5) devices. The bulk of the photons emitted towards the top of the device will be internally reflected and those not reabsorbed by the quantum wells will be absorbed in the lower cell at an energy where the quantum efficiency of the bottom cell is very high and also contribute to the output current. Furthermore, the photons from the unavoidable radiative recombination in the bottom cell are at energies corresponding to the bottom of the well of the lower band-gap cell as shown in FIG. 9. The photons from the radiative recombination in the bottom cell which are directed towards the substrate can be absorbed by an active Ge substrate and contribute to the output current. The photons emitted towards the top of the device from the lower band-gap cell will not be absorbed by the top cell but a high proportion of them will be internally reflected at the top surface and those that are not reabsorbed in the quantum wells of the lower cell can be absorbed by an active Ge substrate and contribute to the output current.

It should be noticed that the fact that the radiative recombination occurs in the SB-QWSC of the top and bottom cell is important to the efficient operation of the device. In a conventional bulk single or multiple junction solar cell limited radiative recombination may occur if the material quality is good enough. The energy of the radiative photons is comparable with the bulk-band gap of the conventional cell and some will be absorbed in other parts of the same cell. If the radiative recombination is significant in these other regions then this can result in the phenomenon of “photon recycling” due to the absorption and re-emission of photons in the same cell. However if the re-absorption occurs in regions where non-radiative recombination is high, such as near the tunnel junction, then the same-cell photon recycling will not be efficient.

The mechanism which will operate in the double SB-QWSC multi-junction cell is different, in that the photons are emitted from the MQW region of the cell where radiative recombination dominates. The majority bulk of the photons have energy too low to be re-absorption in the bulk regions of this cell, or in the tunnel junction, and are reabsorbed in a region of the lower band-gap cell where FIG. 9 indicates that carrier collection is very efficient. The mechanism is one of inter-cell photonic coupling between cells with high radiative efficiency rather than intra-cell photon recycling.

The latter mechanism will also occur in the SB-QWSC whenever there is more than one QW in the system. This recycling will result in re-absorption in a QW in the same cell where the radiative efficiency is high. This recycling process will effectively extend the radiative lifetime of the carriers.

It should also be noted that the inter-cell photonic coupling will also take place if the tunnel junction between the top and bottom cell is removed and the polarity of the bottom cell inverted so that a p-i-n cell is replaced by a n-i-p cell or vice versa. The common polarity region between the top and bottom cells can then be contacted externally in a three-terminal configuration. The inter-cell photonic coupling will also take place if the tunnel junction between the bottom cell and an active Ge substrate is removed and the polarity of the active Ge cell is inverted and the common polarity region between the two cells is contacted externally in a three-terminal configuration. This can be done with and without a tandem top cell. If present, the top cell can have a tunnel or three terminal connection to the bottom cell and the inter-cell photonic coupling still takes place.

The double SB-QWSC and the tandem of SB-QWSC plus active Ge substrate can be constructed to have a superior temperature coefficient of efficiency to conventional cells. All GaAs based solar cells lose efficiency as the temperature increases because the band gap shrinks. It was claimed in Ref. 24 that a solar cell with a deep well MQW in the depletion region would have advantages at concentrator temperatures over a conventional bulk cell. It has been demonstrated that some MQW solar cells have better temperature coefficient of efficiency than control cells without wells [25]. In addition, as the temperature increases, the radiative recombination will increase and the extra radiative coupling to the lower cell will help to off-set the efficiency loss due to the band-gap shrinkage.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope and spirit of the invention as defined by the appended claims.

References

1. J. S. Ward, M. W. Wanlass, K. A. Emery, T. J. Coutts, Proc. 23rd IEEE Photovoltaic Specialists Conf., Louisville, (1993), p. 650.
2. M. A. Green, K. Emery, D. L. King, S. Igari and W. Warta, Prog. Photovolt: Res. Appl., 12, 55, (2004).
3. N. J. Ekins-Daukes, J. M. Barnes, K. W. J. Barnham, J. P. Connolly, M. Mazzer, J. C. Clark, R. Grey, G. Hill, M. A. Pate, J. S. Roberts, Solar Energy Materials and Solar Cells, 68, 71, (2001).
4. C. H. Henry, J. Appl. Phys. 51, 4494 (1980).
5. S. Kurtz, D. Meyers and J. M. Olson, Proc. 26th IEEE Photovoltaic Specialists Conf., Annaheim, (1997), p. 875.
6. K. W. J. Barnham et al., U.S. patent application Ser. No. 09/955,297.
7. N. J. Ekins-Daukes, K. W. J. Barnham, J. P Connolly, J. S. Roberts, et al., Appl. Phys. Lett. 75, 4195, (1999).
8. A. Freundlich, U.S. Pat. Nos. 6,147,296, 6,372,980.
9. K. W. J. Barnham et al. to be submitted to Applied Physics Letters.
10. K. W. J. Barnham et al., “Recent Results on Quantum Well Solar Cells” to be published in Proc. 3^{rd} World Conference on Photovoltaic Energy Conversion, Osaka (2003).
11. S. M. Sze. “The Physics of Semiconductor Devices” 2^{nd} Edition, Wiley, 1981.
12. S. P. Tobin, S. M. Vernon, C. Bajgar, L. M. Geoffroy, C. J. Keavney, M. M. Sanfacon and V. E. Haven, Solar Cells, 24, 103, (1988).
13. S. R. Kurtz, J. M. Olson and A. Kibbler, Proc. 21^{st} IEEE Photovoltaic Specialists Conf., Kissimmee, (1990), p 138.
14. J. Nelson, J. Barnes, N. J. Ekins-Daukes, B. Kluftinger, et al., J. Appl. Phys., 82, 6240, (1997).
15. K. W. J. Barnham, I. Ballard, J. P. Connolly, N. J. Ekins-Daukes, B. G. Kluftinger, J. Nelson, C. Rohr, “Quantum Well Solar Cells”, Physica E: Low-dim. Systems and Nanostructures, 14, 27, (2002).
16 F. Dimroth, P. Lanyi, U. Schubert and A. W. Bett, Journal of Electronic Materials, 29, 42, (2000).
17. R. R. King, C. M. Fetzer, P. C. Colter, K. M. Edmonson, D. C. Law, A. P. Stavrides, H. Yoon, G. S. Kinsey, H. L. Cotal, J. H. Ermer, R. A. Sherif, K. Emery, W. Metzger, R. K. Ahrenkiel, H. N. Karam, “Lattice-Matched and Metamorphic GaInP/GaInAs/Ge Concentrator Solar Cells”, to be published in Proc. 3^{rd} World Conference on Photovoltaic Energy Conversion, Osaka (2003).
18. K. W. J. Barnham et al. to be submitted to Applied Physics Letters.
19. J. C. Connolly, J. Nelson, et al., Proc. 17^{th} European Photovoltaic Solar Energy Conf., Munich, 204 (2001).
20. J. Nelson, J. Barnes, N. J. Ekins-Daukes, B. Kluftinger, et al., J. Appl. Phys., 82, 6240, (1997).
21. A. Freundlich, U.S. Pat. Nos. 6,147,296, 6,372,980.
22. P. R. Griffin, J. Barnes, K. W. J. Barnham, M. Mazzer, et al., J. Appl. Phys., 80, 5815, (1996).
23. N. J. Ekins-Daukes J. M. Barnes, K. W. J. Barnham, J. P. Connolly, M. Mazzer, et al., Solar Energy Materials and Solar Cells, 68, 71, (2001).
24. K. W. J. Barnham, U.K. Patent PCT/GB92/01913, E.C. Patent 92921571.3, U.S. Pat. No. 211,850, Australian Patent 27905/92, “Solar Cell”.
25. I. Ballard, K. W. J. Barnham, J. Nelson, J. Barnes, A. Zachariou, J. Connolly, C. Roberts, J. Roberts, M. Pate, “The Effect of Temperature on the Efficiency of Multi-Quantum Well Solar Cells”, Proc. 2^{nd} World PV Solar Energy Conf., Vienna, 1998.

1. A method of operating a solar cell having a strain balanced multiple quantum well stack containing greater than thirty quantum wells and disposed between bulk semiconductor regions, a band-gap difference between a band-gap of a deepest well within said strain balanced multiple quantum well stack and a band-gap of said bulk semiconductor regions of the cell outside the multiple quantum well region being greater than 60 meV, said method comprises the steps of:
receiving incident radiation having an intensity of greater than one hundred suns concentration;
absorbing photons from said incident radiation both within and outside said quantum well stack to generate electron hole pairs;
recombining electrons and holes with a radiative recombination mechanism to form re-radiated photons that are re-absorbable within said solar cell to generate electrical energy; wherein
electrons and holes within said quantum well stack substantially only recombine via said radiative recombination mechanism.

2. A method as claimed in claim 1, wherein said quantum well stack has an absorption edge above 0.9 μm.

3. A method as claimed in claim 1, wherein said solar cell has a p region and an n region, said p region and said n region having band gap greater than a photon energy corresponding to an absorption edge of said solar cell so as to suppress Shockley recombination of electrons and holes.

4. A method as in claim 1, wherein said solar cell has one of a multiple-layer reflector or a Bragg stack beneath said solar cell to form a reflector operative to reflect radiation with an energy between an absorption edge of said quantum well stack and an absorption edge of said bulk semiconductor regions back to said quantum well stack.

5. A method as claimed in claim 1, wherein said solar cell is a tandem solar cell having a further absorption region beneath said quantum well stack and with a band gap such that said re-radiated photons are absorbed with high probability.

6. A method as claimed in claim 5, wherein said further absorption region is a further strain balanced multiple quantum well stack having greater than thirty quantum wells.

7. A method as in claim 5 wherein said further absorption region is an active Germanium substrate.

8. A method as claimed in claim 1 wherein said quantum well stack comprises GaAs₁₋ₓPₓ/In_{y}Ga_{1-y}As layers, where x and y are chosen so that an equilibrium lattice parameter of said quantum well stack as a free standing structure is substantially equal to a lattice parameter of a substrate of said solar cell for a given absorption edge and produce strain-balanced quantum well layers and quantum well barriers.

9. A method as claimed in claim 1, wherein said quantum well stack comprises GaₓIn₁₋ₓP/In_{y}Ga_{1-y}As layers, where x and y are chosen so that an equilibrium lattice parameter of said quantum well stack as a free standing structure is substantially equal to a lattice parameter of a substrate of said solar cell for a given absorption edge and produce strain-balanced quantum well layers and quantum well barriers.

10. A method as claimed in claim 1, wherein said quantum well stack comprises GaAsₓP₁₋ₓ/In_{y}Ga_{1-y}AsN_{z} layers, where x, y and z are chosen so that an equilibrium lattice parameter of said quantum well stack as a free standing structure is substantially equal to a lattice parameter of a substrate of said solar cell for a given absorption edge and produce strain-balanced quantum well layers and quantum well barriers and z represents the addition of a small proportion of Nitrogen atoms

11. A method as claimed in claim 8, wherein said solar cell has a multiple-layer reflector or Bragg stack grown beneath said solar cell which forms a reflector operative to reflect the radiation with energy between said absorption edge of said quantum well stack and an absorption edge of said bulk semiconductor regions back to said quantum well stack with high reflectivity over a large distribution of incidence angles.

12. A method as claimed in claim 9, wherein said solar cell has a multiple-layer reflector or Bragg stack grown beneath said solar cell which forms a reflector operative to reflect the radiation with energy between said absorption edge of said quantum well stack and an absorption edge of said bulk semiconductor regions back to said quantum well stack with high reflectivity over a large distribution of incidence angles.

13. A method as claimed in claim 10, wherein said solar cell has a multiple-layer reflector or Bragg stack grown beneath said solar cell which forms a reflector operative to reflect the radiation with energy between said absorption edge of said quantum well stack and an absorption edge of said bulk semiconductor regions back to said quantum well stack with high reflectivity over a large distribution of incidence angles.

14. A method as claimed in claim 8, wherein said solar cell has a further absorption region provided by an active Germanium substrate.

15. A method as claimed in claim 9, wherein said solar cell has a further absorption region provided by an active Germanium substrate.

16. A method as claimed in claim 10, wherein said solar cell has a further absorption region provided by an active Germanium substrate.

17. A method as claimed in claim 5, wherein said tandem solar cell contains a quantum well stack comprising GaₓIn₁₋ₓP/Ga_{y}In_{1-y}P layers, where x and y are chosen to substantially minimise stress and said further strain balanced multiple quantum well stack comprises GaAs₁₋ₓPₓ/In_{y}Ga_{1-y}As layers where x and y are chosen so that a equilibrium lattice parameter of said further stack as a free standing structure is substantially equal to a lattice parameter of a substrate of said tandem solar cell for a given absorption edge.

18. A method as claimed in claim 5, wherein said tandem solar cell contains a quantum well stack comprising GaₓIn₁₋ₓP/Ga_{y}In_{1-y}P layers, where x and y are chosen so that an equilibrium lattice parameter of said quantum well stack as a free standing structure is substantially equal to the lattice parameter of a substrate of said tandem solar cell for a given absorption edge and said further strain balanced multiple quantum well stack comprises GaAs₁₋ₓPₓ/In_{y}Ga_{1-y}AsN_{z} where x, y and z are chosen to substantially minimise stress.

19. A method as claimed in claim 17, wherein said further strain-balanced quantum well solar cell has a multiple-layer reflector or Bragg stack grown beneath said tandem solar cell which forms a reflector designed to reflect radiation with energy between an absorption edge of the quantum well stack and an absorption edge of said bulk semiconductor region back to the quantum well stack with high reflectivity over a large distribution of incidence angles.

20. A method as claimed in claim 18, wherein said further strain-balanced quantum well solar cell has a multiple-layer reflector or Bragg stack grown beneath said tandem solar cell which forms a reflector designed to reflect radiation with energy between an absorption edge of the quantum well stack and an absorption edge of said bulk semiconductor region back to the quantum well stack with high reflectivity over a large distribution of incidence angles.

21. A method as claimed in claim 17, wherein a further absorbing region is provided by an active Germanium substrate.

22. A method as claimed in claim 18, wherein a further absorbing region is provided by an active Germanium substrate.
